(19) United States
(12) Patent Application Publication
(10) Pub. No.: US 2019/0190486 A1
(43) Pub. Date: Jun. 20, 2019

(54) PIEZOELECTRIC RESONATOR UNIT

(71) Applicant: Murata Manufacturing Co., Ltd., Nagaokakyo-shi (JP)

(72) Inventors: Atsushi Sugimasa, Nagaokakyo-shi (JP); Koki Sai, Nagaokakyo-shi (JP)

(21) Appl. No.: 16/282,761

(22) Filed: Feb. 22, 2019

Related U.S. Application Data
(63) Continuation of application No. PCT/JP2017/030561, filed on Aug. 25, 2017.

(30) Foreign Application Priority Data
Aug. 31, 2016 (JP) 2016-169901

(51) Int. Cl. H03H 9/09; H03H 9/19; H03H 9/17; H03H 9/05

(52) U.S. Cl. CPC H03H 9/09; H03H 9/0509; H03H 9/173; H03H 9/19

(57) ABSTRACT

A piezoelectric resonator unit that includes a piezoelectric resonator, a substrate that has a first main surface and a second main surface that face each other, and an electroconductive holding member that holds the piezoelectric resonator on the first main surface of the substrate. The electroconductive holding member includes a plurality of metal particles and a plurality of spherical spacers that position the piezoelectric resonator at a predetermined distance from the first main surface of the substrate. A relationship Wₐᵥₑ<{(2/√3)−1}×Vₐᵥₑ is satisfied, where Vₐᵥₑ is an average particle diameter of the spherical spacers and Wₐᵥₑ is an average particle diameter of the metal particles.

### CROSS REFERENCE TO RELATED APPLICATIONS

The present application is a continuation of International application No. PCT/JP2017/030561, filed Aug. 25, 2017, which claims priority to Japanese Patent Application No. 2016-169901, filed Aug. 31, 2016, the entire contents of each of which are incorporated herein by reference.

### FIELD OF THE INVENTION

The present invention relates to a piezoelectric resonator unit, and, in particular, to a piezoelectric resonator unit in which a piezoelectric resonator is held on a substrate by an electroconductive holding member.

### BACKGROUND OF THE INVENTION

A structure in which a piezoelectric resonator is placed on a main surface of a substrate is known as a type of piezoelectric resonator unit. In such a structure, it is desirable to maintain the distance between the piezoelectric resonator and the main surface of the substrate constant so that variation in parasitic capacity, which is generated between an electrode formed on the piezoelectric resonator and an electrode formed on the substrate, can be suppressed. For example, Patent Document 1 discloses a piezoelectric device in which spherical spacers are mixed in an adhesive, which serves as a holding member for holding a piezoelectric element, and a gap between a substrate and the piezoelectric element is maintained due to the diameter of the spherical spacers. Metal particles having an outer diameter of ¼ or smaller of the diameter of the spherical spacers are mixed in the adhesive so that the adhesive can conduct electricity.

Patent Document 1: Japanese Unexamined Patent Application Publication No. 2014-150452

### SUMMARY OF THE INVENTION

However, the piezoelectric device disclosed in Patent Document 1 has a problem in that the electroconductivity of the adhesive is low because the metal particles do not sufficiently enter gaps in the holding member that are formed by the spherical spacers.

The present invention has been made in consideration of the above circumstances, and an object thereof is to provide a piezoelectric resonator unit in which the electroconductivity of a holding portion that holds a piezoelectric resonator is improved while maintaining the distance between the piezoelectric resonator and a substrate main surface constant.

A piezoelectric resonator unit according to an aspect of the present invention includes a piezoelectric resonator, a substrate that has a first main surface and a second main surface that face each other, and an electroconductive holding member that holds the piezoelectric resonator on the first main surface of the substrate. The electroconductive holding member includes a plurality of metal particles and a plurality of spherical spacers, the plurality of spherical spacers positioning the piezoelectric resonator at a predetermined distance from the first main surface of the substrate. A relationship Wₐᵥₑ<{(2/√3)−1}×Vₐᵥₑ is satisfied, where Vₐᵥₑ is an average particle diameter of the spherical spacers and Wₐᵥₑ is an average particle diameter of the metal particles.

With the structure described above, in a holding portion that holds the piezoelectric resonator, the metal particles can sufficiently enter gaps formed between the spherical spacers. Accordingly, the electroconductivity of the holding portion is improved.

With the present invention, it is possible to provide a piezoelectric resonator unit in which the electroconductivity of a holding portion that holds a piezoelectric resonator is improved while maintaining the distance between the piezoelectric resonator and a substrate main surface constant.

### BRIEF DESCRIPTION OF THE DRAWINGS

FIG. 1 is an exploded perspective view of a piezoelectric resonator unit according to an embodiment of the present invention.

FIG. 2 is a sectional view taken along line II-II of FIG. 1.

FIG. 3 is a schematic top view of an electroconductive holding member, specifically illustrating a state in which an adhesive 400, a plurality of spherical spacers 410, and a plurality of metal particles 420 are included in an electroconductive holding member 342.

FIG. 4 is a conceptual diagram illustrating the relationship between the size of spherical spacers and the size of metal particles, specifically illustrating a state in which one metal particle enters a gap that is formed by three spherical spacers.

FIG. 5 is a conceptual diagram illustrating the relationship between the size of spherical spacers and the size of metal particles, specifically illustrating a state in which three metal particles enter a gap that is formed by three spherical spacers.

### DETAILED DESCRIPTION OF THE PREFERRED EMBODIMENTS

Hereinafter, embodiments of the present invention will be described. In the following description related to the drawings, elements that are the same as or similar to each other will be denoted by the same or similar numerals. The drawings are exemplary, the dimensions and shapes of elements are schematic, and the technical scope of the present invention is not limited to the embodiments.

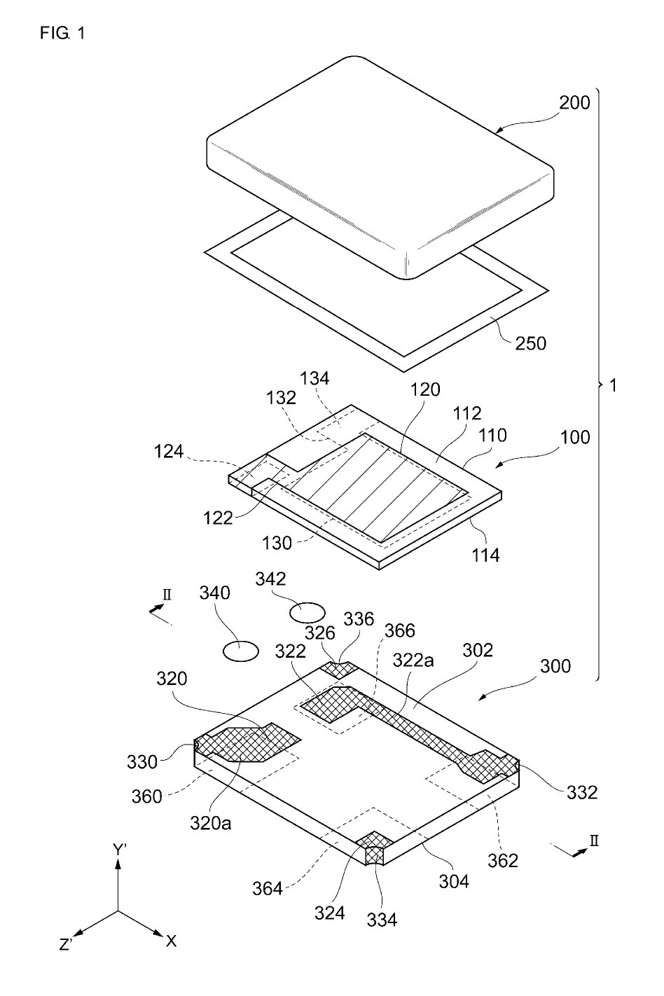

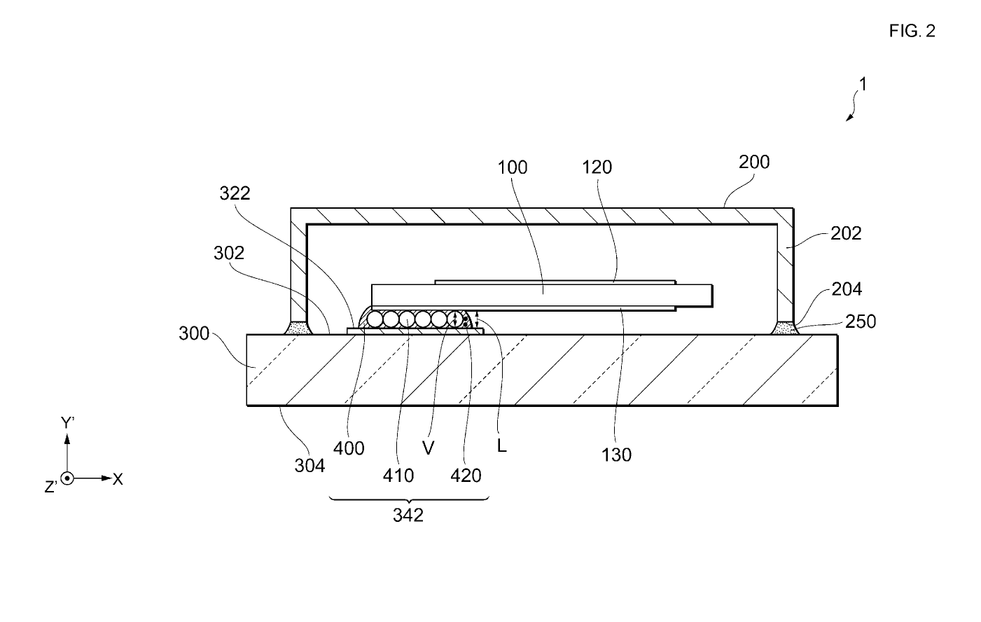

Referring to FIGS. 1 and 2, a piezoelectric resonator unit 1 according to an embodiment of the present invention will be described. FIG. 1 is an exploded perspective view of a piezoelectric resonator unit according to an embodiment of the present invention. FIG. 2 is a sectional view taken along line II-II of FIG. 1.

As illustrated in FIG. 1, the piezoelectric resonator unit 1 according to the present embodiment includes a piezoelectric resonator 100, a lid member 200, and a substrate 300. The lid member 200 and the substrate 300 are parts of a structure of a holding unit (case or package) for accommodating the piezoelectric resonator 100.

The piezoelectric resonator 100 includes a piezoelectric substrate 110 and excitation electrodes 120 and 130 (hereinafter, also referred to as “first excitation electrode 120” and “second excitation electrode 130”) that are respectively disposed on front and back surfaces of the piezoelectric substrate 110.

The piezoelectric substrate 110 is made of a predetermined piezoelectric material, and the material is not particularly limited. In the example shown in FIG. 1, the piezoelectric substrate 110 is made of a synthetic quartz crystal having a predetermined crystal orientation. The piezoelectric substrate 110 is, for example, an AT-cut quartz crystal element. An AT-cut quartz crystal element is cut so that, when an X-axis, a Y-axis, and a Z-axis are the crystal axes of a synthetic quartz crystal and a Y′-axis and a Z′-axis are respectively axes that are obtained by rotating the Y-axis and the Z-axis around the X-axis by 35 degrees 15 minutes±1 minute 30 seconds in a direction from the Y-axis toward the Z-axis, the quartz crystal element has a main surface that is parallel to a plane defined by the X-axis and the Z′-axis (hereinafter, referred to as “XZ′-plane”, and the same applies to planes defined by the other axes). In the example illustrated in FIG. 1, the piezoelectric substrate 110, which is an AT-cut quartz crystal element, has long sides that extend along the X-axis, short sides that extend along the Z′-axis, and sides in the thickness direction that extend along the Y′-axis. The piezoelectric substrate 110 has a substantially rectangular shape in the XZ′-plane. A quartz crystal resonator using an AT-cut quartz crystal element has high frequency stability in a wide temperature range and has high durability. A piezoelectric resonator (that is, a quartz crystal resonator) using an AT-cut quartz crystal element includes a thickness shear mode as main vibration. Hereinafter, elements of the piezoelectric resonator unit 1 will be described with reference to the axial directions of AT-cut.

A piezoelectric substrate is not limited to a substrate having the structure described above. For example, a rectangular AT-cut quartz crystal element that has long sides extending along the Z′-axis and short sides extending along the X-axis may be used as the piezoelectric substrate. Alternatively, the piezoelectric substrate may be a quartz crystal element that is not an AT-cut quartz crystal element, such as a BT-cut quartz crystal element, as long as the main vibration thereof includes a thickness shear mode. The material of the piezoelectric substrate is not limited to quartz and may be another piezoelectric material that is, for example, a piezoelectric ceramic such as PZT or zinc oxide. The piezoelectric resonator may be, for example, a microelectromechanical system (MEMS). To be specific, a Si-MEMS, in which a MEMS is formed in a silicon substrate, may be used. Further, the piezoelectric resonator may be a piezoelectric MEMS that is formed by using a predetermined piezoelectric material, such as AIN, LiTaO₃, LiNbO₃, or PZT.

The first excitation electrode 120 is formed on a first main surface 112 of the piezoelectric substrate 110, and the second excitation electrode 130 is formed on a second main surface 114 of the piezoelectric substrate 110. The first excitation electrode 120 and the second excitation electrode 130, which are a pair of electrodes, are disposed so that substantially the entireties thereof overlap when the XZ′-plane is seen in a plan view.

A connection electrode 124 and a connection electrode 134 are formed on the piezoelectric substrate 110. The connection electrode 124 is electrically connected to the first excitation electrode 120 via an extension electrode 122, and the connection electrode 134 is electrically connected to the second excitation electrode 130 via an extension electrode 132. To be specific, the extension electrode 122 extends on the first main surface 112 from the first excitation electrode 120 toward a short side on the negative X side, passes along a side surface of the piezoelectric substrate 110 on the positive Z′ side, and is connected to the connection electrode 124 formed on the second main surface 114. The extension electrode 132 extends on the second main surface 114 from the second excitation electrode 130 toward a short side on the negative X side, and is connected to the connection electrode 134 formed on the second main surface 114. The connection electrodes 124 and 134 are disposed along the short side on the negative X side, are electrically connected to and mechanically held by the substrate 300 via electroconductive holding members 340 and 342 (holding portion). The dispositions and the patterns of the connection electrodes 124 and 134 and the extension electrodes 122 and 132 are not limited and may be appropriately modified in consideration of electrical connection with other members.

The electrodes described above, including the first excitation electrode 120 and the second excitation electrode 130, for example, each include a chromium (Cr) underlying layer, which is formed on a surface of the piezoelectric substrate 110 to increase the bonding strength, and a gold (Au) layer formed on the surface of the chromium layer. The materials of these electrodes are not limited.

As illustrated in FIG. 2, the lid member 200 has a recess that has an opening that faces a first main surface 302 of the substrate 300. The lid member 200 has a side wall 202 that is formed so as to stand on a bottom surface of the recess along the entire periphery of the opening. The side wall 202 has an end surface 204 that faces the first main surface 302 of the substrate 300. The end surface 204 is joined to the first main surface 302 of the substrate 300 via a joining material 250. The shape of the lid member 200 is not particularly limited, as long as the lid member 200 can accommodate the piezoelectric resonator 100 in an inner space thereof when the lid member 200 is joined to the substrate 300. Although the material of the lid member 200 is not particularly limited, the material may include an electroconductive material such as a metal. In this case, by electrically connecting the lid member 200 to a ground potential, it is possible to additionally provide a shielding function to the lid member 200. When forming the lid member 200 from a metal, for example, the lid member 200 may be formed from an alloy including iron (Fe) and nickel (Ni) (such as 42 alloy). A surface layer, such as a gold (Au) layer, may be further formed on the surface of the lid member 200. By forming a gold layer on the surface, oxidation of the lid member 200 can be prevented. Alternatively, the lid member 200 may have a composite structure made from an insulating material or an electroconductive material and an insulating material.

Referring back to FIG. 1, the substrate 300 holds the piezoelectric resonator 100. In the example shown in FIG. 1, the piezoelectric resonator 100 is excitably held on the first main surface 302 of the substrate 300 via the electroconductive holding members 340 and 342.

The substrate 300 has long sides that extend along the X-axis, short sides that extend along the Z′-axis, and sides in the thickness direction that extend along the Y′-axis. The substrate 300 has a substantially rectangular shape in the XZ′-plane. The substrate 300 is formed from, for example, a single-layer insulating ceramic. As another embodiment, the substrate 300 may be formed by stacking a plurality of insulating ceramic sheets and by firing the ceramic sheets. Preferably, the substrate 300 is made of a heat-resistant material. The substrate 300 may have a flat-plate like shape as illustrated in FIG. 1, or may have a recessed shape that has an opening that faces the lid member 200.

Connection electrodes 320 and 322, corner electrodes 324 and 326, and extension electrodes 320a and 322a are formed on the first main surface 302 of the substrate 300. Side electrodes 330, 332, 334, and 336 are formed on side surfaces of the substrate 300. Outer electrodes 360, 362, 364, and 366 are formed on a second main surface 304 of the substrate 300.

The connection electrodes 320 and 322 are formed on the first main surface 302 of the substrate 300 along a short side on the negative X side and at a distance from the short side. The connection electrode 320 is connected to the connection electrode 124 of the piezoelectric resonator 100 via the electroconductive holding member 340. The connection electrode 322 is connected to the connection electrode 134 of the piezoelectric resonator 100 via the electroconductive holding member 342. Although the material of the connection electrodes 320 and 322 is not particularly limited, for example, the connection electrodes 320 and 322 are formed by stacking molybdenum (Mo), nickel (Ni), and gold (Au) layers. The electroconductive holding members 340 and 342 are formed, for example, by thermally solidifying an adhesive. Details of the structure of the electroconductive holding members 340 and 342 will be described below.

The extension electrode 320a extends from the connection electrode 320 to a side electrode 330 disposed at a corner of the substrate 300. The extension electrode 322a extends in the X-axis direction from the connection electrode 322 to the side electrode 332 disposed at a corner of the substrate 300 diagonal to the side electrode 330.

In the present embodiment, corner electrodes 324 and 326 are formed at the remaining corners (corners where the extension electrodes 320a and 322a, which are electrically connected to the connection electrodes 320 and 322, are not disposed). The corner electrodes 324 and 326 are not connected to any of the first excitation electrode 120 and the second excitation electrode 130.

The plurality of side electrodes 330, 332, 334, and 336 are respectively formed on side surfaces near the corners of the substrate 300. The plurality of outer electrodes 360, 362, 364, and 366 are respectively formed on the second main surface 304 at positions near the corners of the substrate 300. To be specific, the side electrode 330 and the outer electrode 360 are disposed at a corner on the negative X and positive Z′ side, the side electrode 332 and the outer electrode 362 are disposed at a corner on the positive X and negative Z′ side, the side electrode 334 and the outer electrode 364 are disposed at a corner on the positive X and positive Z′ side, and the side electrode 336 and the outer electrode 366 are disposed at a corner on the negative X and negative Z′ side.

The side electrodes 330, 332, 334, and 336 are formed to electrically connect electrodes on the first main surface 302 to electrodes on the second main surface 304. In the example shown in FIG. 1, each of the corners of the substrate 300 has a cutout side surface that is formed by partially cutting out the corner in a cylindrically-curved shape (also referred to as a castellation shape). The side electrodes 330, 332, 334, and 336 are formed on the cutout side surfaces. The shape of the each of the corners of the substrate 300 is not limited to this. Each of the corners may be planer, or may have a rectangular shape with four right-angled corners without being cut out in a plan view.

The outer electrodes 360, 362, 364, and 366 are to be electrically connected to a mounting board (not shown). The outer electrodes 360, 362, 364, and 366 are respectively connected to the side electrodes 330, 332, 334, and 336 that are formed on side surfaces of corresponding corners. Thus, the outer electrodes 360, 362, 364, and 366 can be connected to electrodes on the first main surface 302 of the substrate 300 via the side electrodes 330, 332, 334, and 336.

To be specific, among the plurality of outer electrodes, the outer electrode 360 is electrically connected to the first excitation electrode 120 via the side electrode 330, the extension electrode 320a, the connection electrode 320, and the electroconductive holding member 340; and the outer electrode 362 is electrically connected to the second excitation electrode 130 via the side electrode 332, the extension electrode 322a, the connection electrode 322, and the electroconductive holding member 342. That is, the outer electrodes 360 and 362 are input/output terminals that are electrically connected to the first excitation electrode 120 or the second excitation electrode 130.

The remaining outer electrodes 364 and 366 are dummy electrodes that are not electrically connected to the first excitation electrode 120 or the second excitation electrode 130 of the piezoelectric resonator 100. Because outer electrodes can be formed on all corners by forming the outer electrodes 364 and 366, it becomes easy to perform an operation of electrically connecting the piezoelectric resonator unit 1 to other members. The outer electrodes 364 and 366 may have a function as a ground electrode to which a ground potential is supplied. For example, if the lid member 200 is made of an electroconductive material, it is possible to additionally provide the lid member 200 with a shielding function by electrically connecting the lid member 200 to the outer electrodes 364 and 366.

The structures of the connection electrodes, the corner electrodes, the extension electrodes, the side electrodes, and the outer electrodes, which are formed on the substrate 300, are not limited to those described above and may be modified in various ways. For example, the number of outer electrodes is not limited to four, and, for example, the outer electrodes may be only two input/output terminals that are disposed at diagonal corners. The side electrodes are not limited to those disposed at the corners, and may be formed at any of the side surfaces of the substrate 300 excluding the corners. In this case, as already described, cutout side surfaces may be formed by cutting a part of each of the side surfaces in a cylindrical shape, and the side electrodes may be formed on the side surfaces excluding the corners. Moreover, the corner electrodes 324 and 326, the side electrodes 334 and 336, and the outer electrodes 364 and 366 need not be formed. A through-hole may be formed in the substrate 300 so as to extend from the first main surface 302 to the second main surface 304, and the through-hole may be used to electrically connect a connection electrode formed on the first main surface 302 to the second main surface 304.

The joining material 250 is disposed along the entire periphery of each of the lid member 200 and the substrate 300, and joins the end surface 204 of the side wall 202 of the lid member 200 and the first main surface 302 of the substrate 300 to each other. Although the material of the joining material 250 is not particularly limited, the material may be, for example, gold-tin (Au—Sn) eutectic alloy. By joining the lid member and the substrate via a metal, if the lid member is made of an electroconductive material, the lid member and the substrate can be electrical connected to each other. Moreover, sealability can be improved.

When the lid member 200 and the substrate 300 are joined to each other via the joining material 250, the piezoelectric resonator 100 is hermetically sealed in an inner space (cavity) that is surrounded by the recess of the lid member 200 and the substrate 300. In this case, preferably, the inner space is in a vacuum state in which the pressure therein is lower than the atmospheric pressure. In this case, for example, ageing of the first excitation electrode 120 and the second excitation electrode 130 due to oxidation is reduced.

With the structure described above, in the piezoelectric resonator unit 1, an alternating electric field is applied between the pair of the first excitation electrodes 120 and the second excitation electrode 130 of the piezoelectric resonator 100 via the outer electrodes 360 and 362 of the substrate 300. Thus, the piezoelectric substrate 110 vibrates in a vibration mode including a thickness shear mode, and resonance characteristics due to the vibration are obtained.

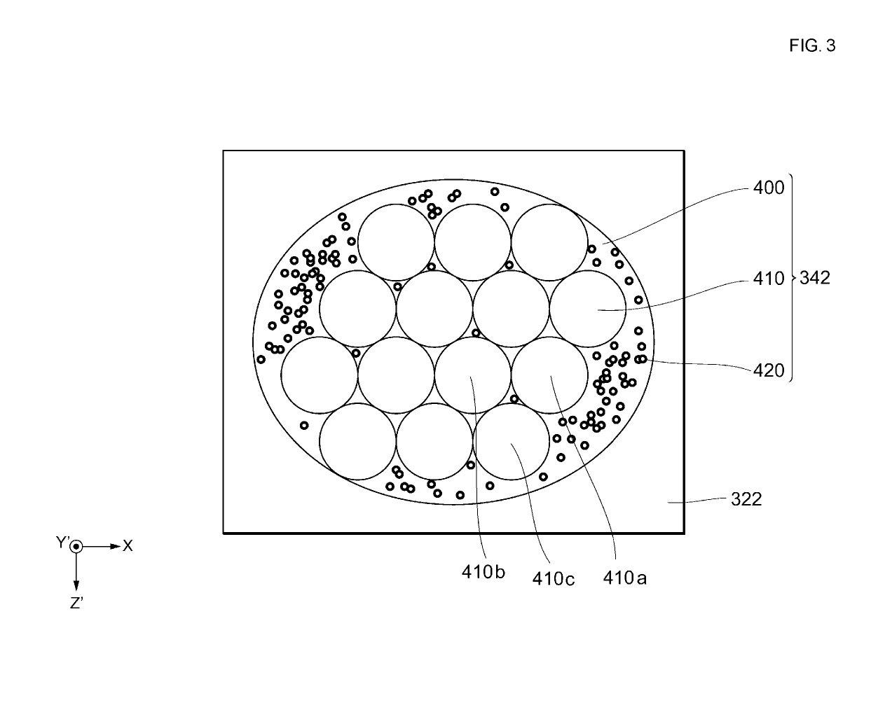

Next, referring to FIGS. 2 and 3, the electroconductive holding members 340 and 342 will be described in detail. FIG. 3 is a schematic top view of an electroconductive holding member, specifically illustrating a state in which an adhesive 400, a plurality of spherical spacers 410, and a plurality of metal particles 420 are included in the electroconductive holding member 342. FIG. 3 schematically illustrates the electroconductive holding member 342, which is disposed on the connection electrode 322, in a plan view of the substrate 300 (that is, a plan view of the XZ′-plane), while omitting the lid member 200 and the piezoelectric resonator 100. The following description will be with reference to holding member 342. Since the detailed description of the electroconductive holding member 340 is similar to the electroconductive holding member 342, a description thereof will be omitted.

As illustrated in FIGS. 2 and 3, the electroconductive holding member 342 includes the adhesive (binder) 400, the plurality of spherical spacers 410, and the plurality of metal particles 420. The adhesive 400 is mainly composed of, for example, a resin.

Each of the plurality of spherical spacers 410 is mainly composed of, for example, a resin. Examples of the resin include an elastic rubber and a plastic such as a silicone resin. In the present embodiment, a silicone resin is used for the plurality of spherical spacers 410. If the adhesive 400 and the spherical spacers 410 are each mainly composed of a resin, the adhesive 400 and the spherical spacers 410 may be differentiated by, for example, using different resins as the materials thereof. If the main component of the adhesive 400 and the material of the spherical spacers 410 are each a silicone resin, preferably, the spherical spacers 410 that have been solidified beforehand are added to the adhesive 400, whose main component is a silicone resin, so that outgas released from an unbridged resin is not generated. With a structure in which the main component of the adhesive 400 and the spherical spacers 410 include a silicone resin in common, the differences in Young's modulus and linear expansion coefficient between the adhesive 400 and the spherical spacers 410 are small (e.g., Young's modulus of Silicon: 0.01˜0.1, Au: 78, and Cu: 130 [GPa]; and linear expansion coefficient of Silicon: 25˜400, Au: 14, and Cu: 17 [10⁻⁶/K]) , such that stress that is generated at boundary surfaces between the adhesive 400 and the spherical spacers 410 can be reduced. Due to the reduction of the stress, it is possible to prevent a problem of detachment of boundary portions of the adhesive 400 and the spherical spacers 410 or to prevent a problem of removal of the spherical spacers 410 from the adhesive 400. Moreover, because the structure includes the spherical spacers 410 that have been solidified beforehand, release of outgas, such as siloxane, from the adhesive 400 in an unbridged state can be reduced. The plurality of spherical spacers 410 each has, for example, a substantially spherical shape. Here, the term “substantially spherical shape” includes not only a spherical shape but also an elliptical shape, a slightly deformed elliptical shape, and the like. In the present embodiment, each of the plurality of spherical spacers 410 is not covered with a metal, and a silicone resin material, which is an insulator and which is a material of the spherical spacers 410, is exposed on the surface. With the structure in which the surface of each of the spherical spacers 410 is an insulator, even if the spherical spacers 410 are removed from the adhesive 400, a problem of causing a short circuit can be prevented, such as when spacers having a conductive surface are used. The spherical spacers 410 have smaller differences in Young's modulus and acoustic impedance compared with spherical spacers that are covered with a metal.

The plurality of spherical spacers 410 each have a particle diameter V, and the average value of the particle diameter V will be represented as the average particle diameter Vₐᵥₑ. In the present description, the particle diameter V of a spherical spacer is defined as an equivalent circle diameter obtained from the cross-sectional area of the spherical spacer in a cross sectional view. The cross-sectional view is, for example, an image of a cross section of the electroconductive holding member that is obtained by using a scanning ion microscope using a focused ion beam (FIB) at 10000 times magnification. The average particle diameter Vₐᵥₑ is the average value of the particle diameters of one hundred spherical spacers that are obtained by selecting ten particles, each of which is estimated to have the largest length, in each of ten cross sectional images of the electroconductive holding member that are taken along different cross sections. If it is possible to measure the spherical spacers before being added to the electroconductive holding member, the average particle diameter may be measured by using a particle-diameter-distribution measuring device that uses a laser diffraction-scattering method. The definitions of the particle diameter and the average particle diameter also apply to the particle diameter and the average particle diameter of metal particles described below.

In relation to the distance L between the surface of the second excitation electrode 130 formed on the second main surface 114 of the piezoelectric resonator 100 and the surface of the connection electrode 322 formed on the first main surface 302 of the substrate 300, the particle diameter V of the spherical spacers 410 is equal to the distance L or smaller than the distance L (that is, V≤L is satisfied) (see FIG. 2). The piezoelectric resonator 100 is placed on the surface of the connection electrode 322 so that the plurality of spherical spacers 410 are interposed therebetween. Thus, in a direction normal to the first main surface 302 of the substrate 300, that is, in the Y′-axis direction shown in FIG. 2, the piezoelectric resonator 100 is held at a distance, which is determined in accordance with the particle diameter V of the spherical spacers, from the surface of the connection electrode 322. To be specific, for example, if the spherical spacers 410 are arranged in one tier in the Y′-axis direction as illustrated in FIG. 2, the piezoelectric resonator 100 is held at a distance corresponding to the particle diameter V of the spherical spacers 410 (for example, about 5 to 6 μm). Alternatively, for example, if the spherical spacers 410 are stacked in two tiers in the Y′-axis direction, the piezoelectric resonator 100 is held at a distance corresponding to twice the particle diameter V of the spherical spacers 410 (for example, about 10 to 11 μm). The spherical spacers 410 may be slightly deformed by being interposed between the connection electrode 322 and the piezoelectric resonator 100, and the length of the spherical spacers 410 in the Y-axis direction may be smaller than the particle diameter V before bonding. In this way, the distance between the second main surface 114 of the piezoelectric resonator 100 and the first main surface 302 of the substrate 300 is maintained constant, and parasitic capacity generated between the two main surfaces can be maintained constant.

In a plan view of the XZ′-plane, for example, the plurality of spherical spacers 410 are closely packed on the connection electrode 322 (see FIG. 3). Here, the phrase “closely packed” refers to a state in which the spherical spacers 410 that are adjacent to each other are disposed so that the surfaces thereof are in contact with each other, as illustrated in FIG. 3. At this time, as illustrated in FIG. 3, a plurality of spherical-spacer sets, each of which is composed of three spherical spacers 410a, 410b, and 410c that are adjacent to each other, are disposed on the first main surface of the substrate. A gap is formed in a region surrounded by the three spherical spacers 410a to 410c that are adjacent to each other. When a plurality of spherical-spacer sets are stacked in the Y′-axis direction, a gap similar to this gap is formed between spherical-spacer sets that are stacked in the Y′-axis direction.

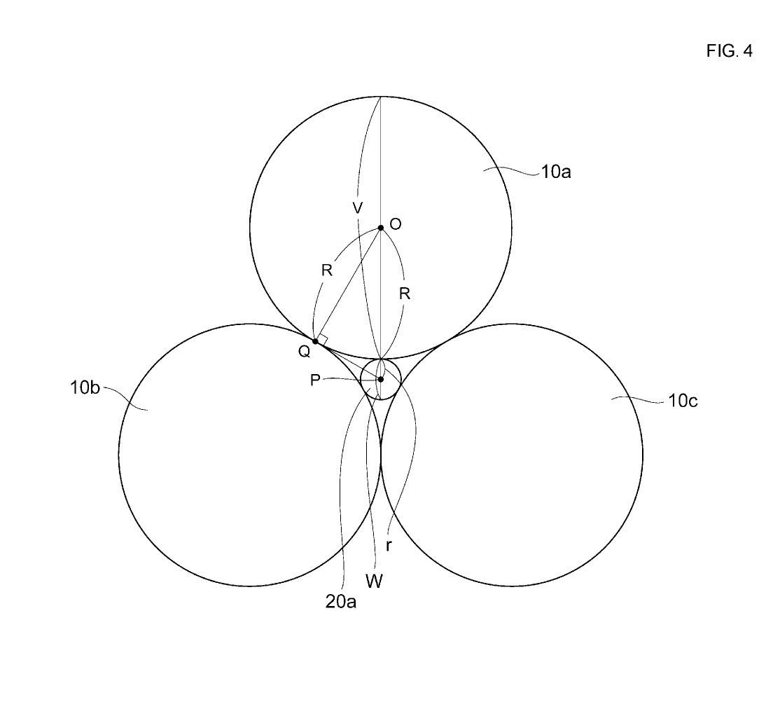

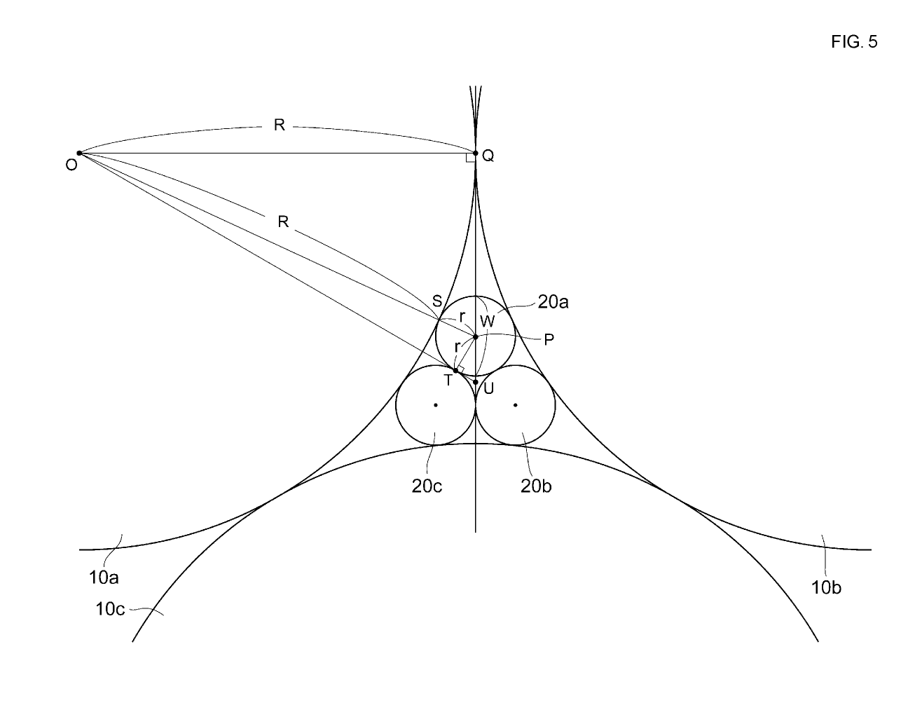

Each of the plurality of metal particles 420 is a particle in which a plurality of metal atoms are bonded. Although the material of the plurality of metal particles 420 is not particularly limited, the material is mainly composed of, for example, silver (Ag) or the like. When the adhesive 400 solidifies while the plurality of metal particles 420 are in contact with each other in the adhesive 400, the electroconductive holding member 342 becomes an adhesive that functions as a holding member while having electroconductivity. The plurality of metal particles 420 each have a particle diameter W, and the average value of the particle diameter W will be represented as the average particle diameter Wₐᵥₑ. Variation in particle diameter of the plurality of metal particles 420 (that is, particle diameter distribution) can be approximated to, for example, a normal distribution function having a standard deviation σ. The plurality of metal particles 420 are each disposed so as to enter a gap formed by the plurality of spherical spacers 410, which are closely packed on the connection electrode 322, and are continuously arranged in contact with each other in the Y′-axis direction. That is, the particle diameter W of the metal particles 420 is smaller than a gap formed by the three spherical spacers 410a to 410c included in the spherical-spacer set. Referring to FIGS. 4 and 5, this point will be described. In FIGS. 4 and 5, it is assumed that the spherical spacers and the metal particle are spheres that circumscribe each other.

FIG. 4 is a conceptual diagram illustrating the relationship between the size of spherical spacers and the size of metal particle, specifically illustrating a state in which one metal particle enters a gap that is formed by three spherical spacers that are arranged adjacent to each other on the first main surface 302 of the substrate 300. FIG. 5 is a conceptual diagram illustrating the relationship between the size of spherical spacers and the size of metal particles, specifically illustrating a state in which three metal particles enter a gap that is formed by three spherical spacers. FIGS. 4 and 5 each schematically illustrate a cross section that is parallel to the XZ′-plane and that is at a height such that the surfaces of a plurality of spherical spacers that are adjacent to each other are in contact with each other when the plurality of spherical spacers are evenly packed as illustrated in FIG. 3. That is, at this height, a gap that is formed by a plurality of spherical spacers is the smallest. The radius of large circles 10a, 10b, and 10c of cross sections of spheres corresponding to the spherical spacers will be denoted by R (corresponding to V/2), and the radius of small circles 20a, 20b, 20c of cross sections of spheres corresponding to the metal particles will be denoted by r (corresponding to W/2).

FIG. 4 is a conceptual diagram illustrating a case where one metal particle enters a gap formed by three spherical spacers of a spherical-spacer set. A line segment OQ=R and a line segment OP=(R+r), where O is the center of the large circle 10a, P is the center of the small circle 20a, and Q is the point of contact between the large circle 10a and the large circle 10b. (the line segment OQ):(the line segment OP)=R:(R+r)=√3:2, because an angle OQP=90 degrees and an angle OPQ=60 degrees in a triangle OPQ. Accordingly, the following equation (1) holds.

r={(2/√3)−1}×R (1)

From equation (1), a condition that allows one metal particle having a particle diameter W to enter a gap formed by three spherical spacers having a particle diameter V is represented by the following inequality (2).

W<{(2/√3)−1}×V (2)

Accordingly, if the following inequality (3) is satisfied, some of a plurality of metal particles having the average particle diameter Wₐᵥₑ can each enter a corresponding one of gaps that are formed by a plurality of spherical spacers having the average particle diameter Vₐᵥₑ. If, for example, the average particle diameter Wₐᵥₑ of the metal particles satisfies Wₐᵥₑ={(2/√3)−1}×Vₐᵥₑ, metal particles whose particle diameter W is smaller than the average particle diameter Wₐᵥₑ can enter the gaps, and the proportion of such metal particles is about a half of metal particles included in the electroconductive holding member.

Wₐᵥₑ<{(2√3)−1}×Vₐᵥₑ(≈0.15×Vₐᵥₑ) (3)

When the particle diameter distribution of metal particles included in the electroconductive holding member is approximated to a normal distribution function having a standard deviation σ, if any of the following inequalities (4) to (6) is further satisfied, most of (for example, if the inequality (5) is satisfied, about 95% of) a plurality of metal particles having the average particle diameter Wₐᵥₑ can enter gaps formed by a plurality of spherical spacers having the average particle diameter Vₐᵥₑ.

Wₐᵥₑ+σ<{(2/√3)−1}ΔVₐᵥₑ (4)

Wₐᵥₑ+2σ<{(2/√3)−1}ΔVₐᵥₑ (5)

Wₐᵥₑ+3σ<{(2/√3)−1}ΔVₐᵥₑ (6)

FIG. 5 is a conceptual diagram illustrating a case where three metal particles enter a gap formed by three spacers in a spherical-spacer set. Regarding each of the large circles 10a, 10b, and 10c, a part of an arc thereof is illustrated. A line segment OQ=R, a line segment OP=(R+r), and a line segment PT=r, where O is the center of the large circle 10a, P is the center of the small circle 20a, Q is the point of contact between the large circle 10a and the large circle 10b, S is the point of contact between the large circle 10a and the small circle 20a, T is the point of contact between the small circle 20a and the small circle 20c, and U is the intersection of a straight line OT and a straight line QP. A line segment OT=√{(R+r)²−r²} from the Pythagorean theorem, because an angle PTO=90 degrees in a triangle POT. A line segment TU=(1/√3)×r, because an angle PTU=90 degrees and an angle PUT=60 degrees in a triangle PTU. Accordingly, a line segment OU=√{(R+r)²−r²}+(1/√3)×r. (the line segment OQ):(the line segment OU)=R:√{(R+r)²−r²}+(1/√3)×r=√3:2, because the angle OQU=90 degrees and an angle OUQ=60 degrees in the triangle OQU. Accordingly, the following equation (7) holds.

r=(5−2√6)×R (7)

From the equation (7), a condition that allows three metal particles having a particle diameter W to enter a gap formed by three spherical spacers having a particle diameter V is represented by the following inequality (8).

W<(5−2√6)×V (8)

Accordingly, if the following inequality (9) is satisfied, some sets of three metal particles included in a plurality of metal particles having the average particle diameter Wₐᵥₑ (for example, about a half of metal particles included in the electroconductive holding member) can each simultaneously enter a corresponding one of gaps that are each formed by three spherical spacers having the average particle diameter Vₐᵥₑ.

Wₐᵥₑ<(5−2√6)×Vₐᵥₑ(≈0.10×Vₐᵥₑ) (9)

With the structure described above, in the piezoelectric resonator unit 1, for example, the metal particles can sufficiently enter the gaps formed by the spherical spacers, compared with an existing adhesive as disclosed in Patent Document 1. Therefore, even though the spherical spacers are mixed therein, the electroconductivity of the electroconductive holding member can be maintained appropriately high. Accordingly, with the piezoelectric resonator unit 1, the electroconductivity of the electroconductive holding member (holding portion), which holds the piezoelectric resonator, is improved while maintaining the distance between the piezoelectric resonator 100 and the main surface of the substrate 300 constant. Moreover, because it is not necessary to cover the spherical spacers with a metal, the manufacturing cost can be reduced, compared with a structure in which spherical spacers are covered with a metal.

Moreover, because spherical spacers that are not covered with a metal are used, for example, the electroconductive holding members 340 and 342 each have small Young's modulus and low acoustic impedance, compared with an existing piezoelectric resonator unit as disclosed in Patent Document 1. Thus, the difference in acoustic impedance between the piezoelectric resonator 100 and the substrate 300, whose acoustic impedances are comparatively high, and the acoustic impedance of the electroconductive holding member, whose acoustic impedance is comparatively low, is large. Here, regarding transmission of vibrations between different objects, reflection waves of vibrations at the boundary surfaces between the objects increase and transmitted waves decrease, as the difference in acoustic impedance between the objects increases. That is, among vibrations that are transmitted from the piezoelectric resonator 100, reflection waves at the boundary surfaces between the piezoelectric resonator 100 and the electroconductive holding members 340 and 342 increase, and transmitted waves to the substrate 300 decrease. Accordingly, vibrations that leak from the piezoelectric resonator 100 via the electroconductive holding members 340 and 342 to the substrate 300 decrease, and decrease of the CI (crystal impedance) value of the piezoelectric resonator unit 1 is suppressed.

Furthermore, when the metal particles have a size such that three metal particles can simultaneously enter a gap formed by three spherical spacers as illustrated in FIG. 5, blocking of the gap by the metal particles due to contact between the metal particles is reduced. Thus, compared with the case shown in FIG. 4, metal particles can more easily enter the gap, and the electroconductivity of the electroconductive holding member is further improved.

The average particle diameter Wₐᵥₑ of the plurality of metal particles may satisfy the following inequality (10). In this case, at least six metal particles can simultaneously enter a gap formed by three spherical spacers. Accordingly, occurrence of powder bridge of metal particles is suppressed, and therefore metal particles can more easily enter the gaps and the electroconductivity of the electroconductive holding member is improved.

Wₐᵥₑ<[{(2/√3)−1}/6]×Vₐᵥₑ(≈0.03×Vₐᵥₑ) (10)

In the example illustrated in FIG. 1, one end of the piezoelectric resonator 100 is fixed by the electroconductive holding members 340 and 342 and the other end is free. However, the piezoelectric resonator 100 may be fixed to the substrate 300 at both ends thereof. That is, the connection electrodes 320 and 322 may be disposed on different sides on the first main surface 302 of the substrate 300. For example, one of the connection electrodes 320 and 322 may be formed on the positive X side, and the other may be formed on the negative X side.

In FIG. 2, the spherical spacers are arranged in one tier in the height direction (Y′-axis direction). However, the number of tiers of the spherical spacers is not limited to one, and two or more tiers may be stacked in the height direction.

In order that, for example, six metal particles can simultaneously enter a gap formed by three spherical spacers, the metal particles need to be small relative to the spherical spacers. However, when the size of the metal particles is reduced, the proportion of the metal particles in the electroconductive holding member increases. As a result, the acoustic impedance of the electroconductive holding member increases. Thus, the difference in acoustic impedance between the electroconductive holding member, and the piezoelectric resonator 100 and the substrate 300 tends to decrease. Accordingly, in order to prevent decrease of the difference in acoustic impedance, preferably, the average particle diameter of the metal particles Wₐᵥₑ satisfies the following inequality (11), so that the number of metal particles that can enter a gap formed by three spherical spacers having the average particle diameter Vₐᵥₑ is, for example, at most six.

Wₐᵥₑ≥[{(2/√3)−1}/6]×Vₐᵥₑ(≈0.03×Vₐᵥₑ) (11)

The piezoelectric resonator unit 1 need not include the lid member 200.

Heretofore, exemplary embodiments of the present invention have been described. In the piezoelectric resonator unit 1, the electroconductive holding members 340 and 342 each include the plurality of metal particles 420 and the plurality of spherical spacers 410, the spherical spacers 410 positioning the piezoelectric resonator 100 at a predetermined distance from the first main surface 302 of the substrate 300; and a relationship Wₐᵥₑ<{(2/√3)−1}×Vₐᵥₑ is satisfied, where Vₐᵥₑ is the average particle diameter of the spherical spacers 410 and Wₐᵥₑ is the average particle diameter of the metal particles 420. Thus, the metal particles 420 sufficiently enter the gaps formed by the spherical spacers 410, and therefore the electroconductivity of the electroconductive holding members 340 and 342 is improved. Moreover, because it is not necessary to cover the spherical spacers with a metal, the manufacturing cost is reduced. Furthermore, because spherical spacers that are not covered with a metal are used, the electroconductive holding members 340 and 342 each have small Young's modulus and low acoustic impedance. Thus, vibrations that leak from the piezoelectric resonator 100 via the electroconductive holding members 340 and 342 to the substrate 300 decrease, and decrease of the CI value of the piezoelectric resonator unit 1 is suppressed.

In the piezoelectric resonator unit 1, a relationship Wₐᵥₑ+2σ<{(2/√3)−1}×Vₐᵥₑ may be further satisfied, where σ is a standard deviation of a normal distribution function to which a particle diameter distribution of the metal particles is approximated. In this case, most of (for example, if the inequality (5) is satisfied, about 95% of) the metal particles 420 can enter the gaps formed by the plurality of spherical spacers 410. Accordingly, the electroconductivity of the electroconductive holding members 340 and 342 is further improved.

In the piezoelectric resonator unit 1, a relationship Wₐᵥₑ<(5−2√6)×Vₐᵥₑ may be further satisfied. In this case, the metal particles 420 can more easily enter the gaps formed by the spherical spacers 410. Accordingly, the electroconductivity of the electroconductive holding members 340 and 342 is further improved. When the surface of each of the spherical spacers 410 is an insulator, if entry of the metal particles 420 into the gaps between adjacent spherical spacers 410 is blocked, electrical resistance increases. If the additive rate of the spherical spacers 410 is reduced so that gaps are formed in such a way that the spherical spacers 410 are separated from each other without becoming adjacent to each other, it is necessary to increase the additive rate of the metal particles 420 in order to obtain electrical conductivity by allowing the metal particles 420 to contact each other. As the additive rate of the metal particles 420 increases, the rigidity of the electroconductive holding member becomes close to that of the metal, and the influence of the electroconductive holding member on excitation of the piezoelectric resonator increases. A structure that satisfies a relationship Wₐᵥₑ<[{(2/√3)−1}/6]×Vₐᵥₑ, and more preferably a relationship Wₐᵥₑ<<(5−2√6)×Vₐᵥₑ can suppress the increase of electrical resistance of the electroconductive holding member and can suppress the increase of the influence of the electroconductive holding member on excitation of the piezoelectric resonator, even if the additive rate of the spherical spacers in the electroconductive holding member is at a high level such that the spherical spacers 410 contact each other.

Although the material of the spherical spacers 410 is not particularly limited, the material may be mainly composed of, for example, a resin.

For example, the surface of each of the spherical spacers 410 may be an insulator. In this case, the acoustic impedance of the spherical spacers 410 is low, compared with spherical spacers that are covered with a metal. Accordingly, vibrations that leak from the piezoelectric resonator 100 via the electroconductive holding members 340 and 342 to the substrate 300 decrease, and therefore decrease of the CI value of the piezoelectric resonator unit 1 is suppressed.

Although the material of the metal particles 420 is not particularly limited, the material may be mainly composed of, for example, silver.

The plurality of spherical spacers 410 may include a spherical-spacer set that is composed of three spherical spacers 410a to 410c that are arranged on the first main surface 302 of the substrate 300 and that are adjacent to each other, and the plurality of metal particles 420 may include a plurality of particles that pass through a gap surrounded by the three spherical spacers 410a to 410c and that are continuously arranged in contact with each other in a direction normal to the first main surface 302.

The three spherical spacers 410a to 410c may be in contact with each other.

A plurality of the spherical-spacer sets may be disposed on the first main surface 302 of the substrate 300.

The piezoelectric resonator unit 1 further includes the lid member 200 that is joined to the substrate 300 and that accommodates the piezoelectric resonator 100. In this case, the piezoelectric resonator 100 can be accommodated in an inner space.

The embodiments, which have been described above in order to facilitate understanding the present invention do not limit the scope of the present invention. The present invention may be modified within the spirit and scope thereof and includes the equivalents thereof. That is, a modification of each of the embodiments that is appropriately modified in design by a person having ordinary skill in the art is included in the scope of the present invention as long as the modification has the features of the present invention. For example, elements of each of the embodiments; and the arrangement, the materials, the shapes, and the sizes of the elements are not limited to those described above as examples and may be modified as appropriate. Elements of the embodiments may be used in a combination as long as the combination is technologically feasible, and such combination is also included in the scope of the present invention as long as the combination has the features of the present invention.

### REFERENCE SIGNS LIST

1 piezoelectric resonator unit
100 piezoelectric resonator
110 piezoelectric substrate
120, 130 excitation electrode
122, 132 extension electrode
124, 134 connection electrode
200 lid member
250 joining material
300 substrate
320, 322 connection electrode
320a, 322a extension electrode
324, 326 corner electrode
330, 332, 334, 336 side electrode
340, 342 electroconductive holding member
360, 362, 364, 366 outer electrode
400 adhesive
410 spherical spacer
420 metal particle
10a, 10b, 10c large circle
20a, 20b, 20c small circle

1. A piezoelectric resonator unit comprising:
a piezoelectric resonator;
a substrate that has a first main surface and a second main surface that face each other; and
an electroconductive holding member that holds the piezoelectric resonator on the first main surface of the substrate, wherein the electroconductive holding member includes:
a plurality of metal particles; and
a plurality of spherical spacers, the plurality of spherical spacers positioning the piezoelectric resonator at a predetermined distance from the first main surface of the substrate, and wherein
Wₐᵥₑ<{(2/√3)−1}×Vₐᵥₑ
where Vₐᵥₑ is an average particle diameter of the spherical spacers and Wₐᵥₑ is an average particle diameter of the metal particles.

2. The piezoelectric resonator unit according to claim 1, wherein
Wₐᵥₑ+σ<{(2/√3)−1}×Vₐᵥₑ
where σ is a standard deviation of a normal distribution function to which a particle diameter distribution of the metal particles is approximated.

3. The piezoelectric resonator unit according to claim 1, wherein
Wₐᵥₑ+2σ<{(2/√3)−1}×Vₐᵥₑ
where σ is a standard deviation of a normal distribution function to which a particle diameter distribution of the metal particles is approximated.

4. The piezoelectric resonator unit according to claim 1, wherein
Wₐᵥₑ+3σ<{(2/√3)−1}×Vₐᵥₑ
where σ is a standard deviation of a normal distribution function to which a particle diameter distribution of the metal particles is approximated.

5. The piezoelectric resonator unit according to claim 1, wherein Wₐᵥₑ<(5−2·6)×Vₐᵥₑ.

6. The piezoelectric resonator unit according to claim 1, wherein Wₐᵥₑ<[{(2/√3)−1}/6]×Vₐᵥₑ.

7. The piezoelectric resonator unit according to claim 1, wherein Wₐᵥₑ≥[{(2/√3)−1}/6]×Vₐᵥₑ.

8. The piezoelectric resonator unit according to claim 1, wherein the plurality of spherical spacers are each mainly composed of a resin.

9. The piezoelectric resonator unit according to claim 8, wherein the resin is selected from an elastic rubber and a silicone resin.

10. The piezoelectric resonator unit according to claim 8, wherein the resin is a silicone resin.

11. The piezoelectric resonator unit according to claim 1, wherein the electroconductive holding member further includes an adhesive.

12. The piezoelectric resonator unit according to claim 11, wherein the adhesive is mainly composed of a first resin.

13. The piezoelectric resonator unit according to claim 12, wherein the first resin is a silicone resin.

14. The piezoelectric resonator unit according to claim 12, wherein the plurality of spherical spacers are each mainly composed of a second resin.

15. The piezoelectric resonator unit according to claim 14, wherein the first resin and the second resin are each a silicone resin.

16. The piezoelectric resonator unit according to claim 1, wherein at least a surface of each of the plurality of spherical spacers is an insulator.

17. The piezoelectric resonator unit according to claim 1, wherein a surface of each of the plurality of spherical spacers is not covered with a metal.

18. The piezoelectric resonator unit according to claim 1, wherein the plurality of metal particles are each mainly composed of silver.

19. The piezoelectric resonator unit according to claim 1, wherein the plurality of spherical spacers include at least one spherical-spacer set that is composed of three spherical spacers continuously arranged in contact with each other on the first main surface and in a direction normal to the first main surface, and
Wherein the Wₐᵥₑ of the plurality of metal particles is at a value that allows the plurality of metal particles to pass into a gap established by the three spherical spacers of the at least one spherical-spacer set.

20. The piezoelectric resonator unit according to claim 19, wherein the three spherical spacers are in direct contact with each other.

21. The piezoelectric resonator unit according to claim 20, wherein the plurality of spherical spacers include a plurality of the spherical-spacer sets disposed on the first main surface.

22. The piezoelectric resonator unit according to claim 1, further comprising a lid member joined to the substrate so as to enclose the piezoelectric resonator between the lid member and the substrate.
